(19) United States
(12) Patent Application Publication
(10) Pub. No.: US 2003/0070931 A1
(43) Pub. Date: Apr. 17, 2003

(54) Selective plating of printed circuit boards

(75) Inventor: Keith G. Kitchens, Eau Claire, WI (US)

Correspondence Address: ROBERT D. FISH; RUTAN & TUCKER, LLP, P.O. BOX 1950, 611 ANTON BLVD., 14TH FLOOR, COSTA MESA, CA, 92628-1950, US

(73) Assignee: Honeywell Advanced Circuits, Inc.

(21) Appl. No.: 09/982,216

(22) Filed: Oct. 17, 2001

(51) Int. Cl. C25D 5/02; H05K 3/00; B32B 3/10

(52) U.S. Cl. 205/118; 205/125; 428/131

(57) ABSTRACT

An improved plating method in which non-plated vias or through holes are temporarily metalized for use as busses during selective noble metal plating and subsequently de-metalized to prevent shorting together of the nobly plated features.

### FIELD OF THE INVENTION

The present invention relates, in general, to the process of plating selective metals on a printed circuit board and, more specifically, to a process for depositing gold on selective areas of a printed circuit board.

### BACKGROUND OF THE INVENTION

Plating selective areas of a printed circuit/wiring board (PWB) with gold can be a challenge as is discussed in U.S. Pat. No. 6,022,466 (herein incorporated by reference in its entirety and hereinafter referred to as the '466 patent). The deficiencies of the conventional processes to selectively plate gold on surface copper features of a PWB (as discussed in the '466 patent) show that a need still exists for a process which can selectively deposit gold on surface copper features after surface etching, thereby avoiding problems with under-cutting, gold overhangs and flake-off.

The process in the '466 patent (hereinafter the “Tamarkin” process) purportedly provides an approach for solving the problem of under-cutting and gold overhang. The Tamarkin process proposes that each area/feature to be gold plated be internally coupled to a second feature which is (a) not to be gold plated, and (b) which is located in a different area of the PWB than the feature being plated. In many instances, the feature that is not to be gold plated is not necessary for the proper functioning of the PWB but is instead a metalized via added simply to facilitate the plating of the feature to be gold plated. As such, the added via takes up valuable space on the PWB. This problem is compounded by the fact that, in order to prevent shorting between gold plated features, separate metalized vias must be provided for each feature to be gold plated. Use of separate metalized vias increases the number of vias that need to be added, as well as the number of internal traces/conductors which couple the features to be gold plated to the added metalized vias.

### SUMMARY OF THE INVENTION

The present invention is directed to an improved plating method wherein non-plated vias or through holes are temporarily metalized for use as busses during noble metal plating and subsequently de-metalized to prevent shorting together of the nobly plated features.

It is contemplated that the non-plated vias or through holes may comprise mounting and/or alignment vias or through holes. A significant space savings can be achieved by utilizing non-plated through holes that are already part of a PWB design as temporary busses during plating. By using mounting holes or other existing non-plated through holes, there is no need to use additional space on a device to be plated for positioning of metalized through holes as suggested by Tamarkin. By using temporary busses, a single bus can be used to short together two or more features to be plated during plating as the bus will be removed prior to when the shorting together of features would be a problem. The ability to share a bus will often allow all bussing requirements to be satisfied by a relatively small number of existing non-plated through holes.

It is further contemplated that removal of the temporary busses used during noble metal plating prior to subsequent plating eliminates the need to mask the nobly plated features during such subsequent plating.

For the sake of clarity, the term “through hole” will be used throughout this disclosure in place of the phrase “via or through hole” and should be interpreted as being a hole extending at least partially through the device having features to be plated.

It should be noted that any described changes made to a printed wiring board can be accomplished by modifying the design of the printed wiring board and then forming a printed wiring board in accordance with the design. Similarly, descriptions of changes to a printed wiring board design may be implemented during formation of a printed wiring board rather than as an actual change to a design document.

Various objects, features, aspects and advantages of the present invention will become more apparent from the following detailed description of preferred embodiments of the invention, along with the accompanying drawings in which like numerals represent like components.

### BRIEF DESCRIPTION OF THE DRAWINGS

FIG. 1a is a cross-section of the multi-layered PWB with features to be plated and internal conductors extending between the features to be plated and a plated through hole

FIG. 1b is a cross-section of the multi-layered PWB of FIG. 1b after plating but prior to stripping of metal from the plated through hole of FIG. 1a.

FIG. 1c is a cross-section of a multi-layered PWB with plated features and internal conductors extending between plated features and a non-plated through hole.

FIGS. 2a-2i are cross-sections of a multi-layered PWB during different process steps of electroplating gold according to one embodiment of the invention.

FIG. 3 is a plan view of the multi-layered PWB taken along section 5-5 of FIG. 2i with a portion of mask 94 having been removed.

FIG. 4 is plan view of an innerlayer utilizing additional interconnect wiring to accommodate electrically isolated through holes.

### DETAILED DESCRIPTION

For a given PWB design, the following steps are preferred as part of a selective plating/metalization method: (i) identifying features of the PWB design which are to be selectively plated (generally with a noble metal) but which will be electrically isolated from the portion of the PWB which will be coupled to a current source during electroplating; (ii) identifying (or possibly adding) non-plated through holes which will be used as temporary busses during plating; (iii) adding conductors/traces which will electrically connect the identified features to be plated with the temporary busses (and possibly adding connectors/traces which will electrically connect the temporary busses to a current source during plating); (iv) forming the temporary busses out of the through holes identified in step (ii) (generally by temporarily plating their walls); (v) selectively plating the features identified in step (i); and (vi) electrically isolating the added conductors/traces from the temporary busses after selective plating is complete.

The first step is to identify features of the PWB design that will be selectively plated (generally with a noble metal) but which will be electrically isolated from the portion of the PWB that will be coupled to a current source during electroplating. During this step all features that will be gold plated are reviewed to see that internal bus connections are present to prevent the feature from being electrically disconnected from the current source. If features are present that are not internally bussed through the original customer supplied design data, additional bussing must be added in steps (iii) and (iv). In some instances, it may be advantageous to include a given feature as such an identified feature even if it is not so electrically isolated if inclusion of an additional trace coupling the feature to a temporary bus will facilitate plating or help prevent damage to the PWB during plating.

The second step, identifying (or possibly adding) non-plated through holes to be used as temporary busses during plating, is also fairly straightforward. Having identified electrically isolated features to be plated, non-plated through holes located close to such features can be examined along with the various layers of the PWB to determine which are suitable for use as a temporary bus. Suitability in this instance will likely be primarily dependent on free space available on the inner layers of the PWB and typical routing constraints applied when adding traces to such layers.

The third step, adding conductors/traces which will electrically connect the identified features to be plated with the temporary busses (and possibly adding connectors/traces which will electrically connect the temporary busses to a current source during plating), will generally be accomplished during formation of the inner layers using the same methods as is used to form any other pads or traces on the inner layers. The preferred technique to rout the additional internal bussing is to start in the center of the PWB signal layers, once the electrically isolated through holes have been identified. To minimize electrical interference, the additional bussing is preferably added on signal layers between the ground layers. It should be noted that in some instances additional pads and conductive traces will need to be added to an inner layer, particularly when trying to couple an added trace to a through hole which does not already have a connection pad on the layer where the trace is being added.

More than one interconnection trace can be added to each non-plated through hole. In this fashion, a large number of electrical interconnections can be made on a small number of non-plated features. By utilizing this technique, there is no outerlayer area sacrificed for the selective metalization features. The maximum number of interconnection busses that may be added to a single non-plated through hole is limited by the minimum spacing requirement of the customer's design.

In the bussing of electrically isolated through holes, a minimum of one interconnection pad is necessary. More interconnection pads per through hole may be added for reliability to ensure the electrical path for selective metalization is present.

It is preferred that the added traces be routed to points which correspond to the center axis of the non-plated through holes which are used as temporary busses. Routing the traces to the center of the area of an inner layer to be removed by drilling will help ensure that the trace terminates at the wall of the through hole once it is drilled so that it will come in contact with plating on the wall of the through holes. It is understood that by terminating the interconnection trace ends in the geometric center of the non-plated through holes, subsequent drilling will electrically disconnect the interconnect trace ends. The interconnect traces will be electrically connected to the surface of the PWB once primary metalization occurs in step (iv). After removal of metalization in step (vi), the interconnect trace ends will be permanently electrically disconnected from all other electrically connected features. In this fashion the final PWB will be returned to the customers original electrical design.

A review of FIG. 4 may clarify the written description of the forgoing steps. FIG. 4 is a view of an inner layer 76b of a PWB 60. The non-plated clearances 68a-d indicate where the non-plated through holes identified in step (ii) will be placed/drilled. Pad 106 is added in step (iii) to the PWB design to provide an electrical interconnection to a through hole to be selectively plated which was identified in step (i) as being electrically isolated from the electroplating current source. The trace 64a, which was added per step in step (ii), provides a connection between added pad 106 and the through hole to be formed at clearance 68a. The circular pad 104 is an interconnect pad to a through hole to be plated which is part of the original PWB design and which is not electrically isolated from the electroplating current source because trace 64b will serve to couple it to an electroplating current source. Trace 64b is a signal path that is part of the original PWB design and need not be added. Pad clearance 102 provides a non-contact pass through point for the plated-through hole.

Interconnection trace 64a is added to connect pad 106 with the non-plated hole to be formed at 68a. Since there is no pad on the non-plated hole the interconnection trace 64a is routed to the geometric center of the hole. When the hole is drilled in final board form, the interconnection trace will form an electrical interface with the hole wall.

Returning to the disclosed method, the fourth step, forming the temporary busses out of the through holes identified in step (ii), is preferably accomplished by allowing the walls of the through hole to be electrolessly plated along with the rest of PWB 60 immediately after the drilling of the various through holes. However, any method which at least partially fills the through holes identified in step (ii) with a conductive material so that any traces terminating at the walls of the through holes are electrically coupled together by such a conductive material may be used. As the board is processed through first metalization, an electrical path for current flow from a current source through the feature coupled to pad 106 of FIG. 4 by way of the electroless copper deposited on the outerlayer surface of PWB 60 and in the non-plated through hole at 68a, and the interconnect trace 64a to pad 106.

Step five, selectively plating the features identified in step (i) will preferably be accomplished by masking portions of PWB 60 which are not to be plated and then electroplating the features identified in step (i).

Step six, electrically isolating the added conductors/traces from the temporary busses after selective plating is complete is preferably accomplished by removing the conductive material added as part of the fourth step. Removal of the conductive material maybe accomplished by any means, but it is thought that etching and/or drilling may be advantageously used to remove the material.

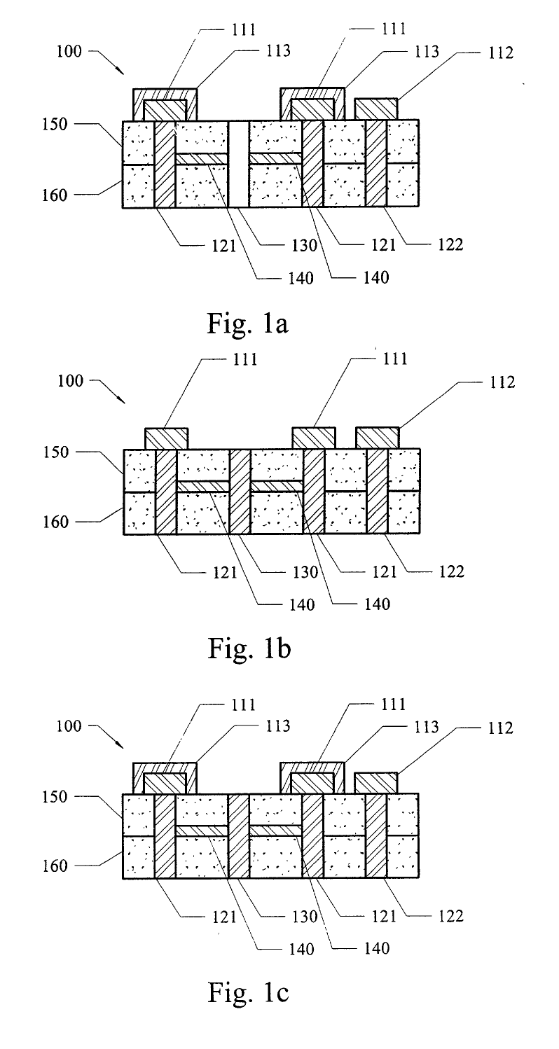

FIGS. 1a-c provide a first example of the selective plating method. Looking at FIG. 1a, a PWB design for a device 100 may normally include all the features shown except for conductors/traces 140. In FIG. 1b, features 111 have been selectively plated with noble metal layer 113. In order to selectively plate features 111, features 111 needed to be electrically coupled together through the use of a temporary bus. Such electrical coupling of features 111 was accomplished by modifying the PWB design to include conductors/traces 140 and temporarily filling non-plated through hole 130 with a conductive material as shown. Although through hole 130 could have been an addition to the PWB design, an existing non-plated through hole is preferred instead. After noble metal layers 113 are added to features 111, the conductive material in through hole 130 is removed to leave the device shown in FIG. 1c.

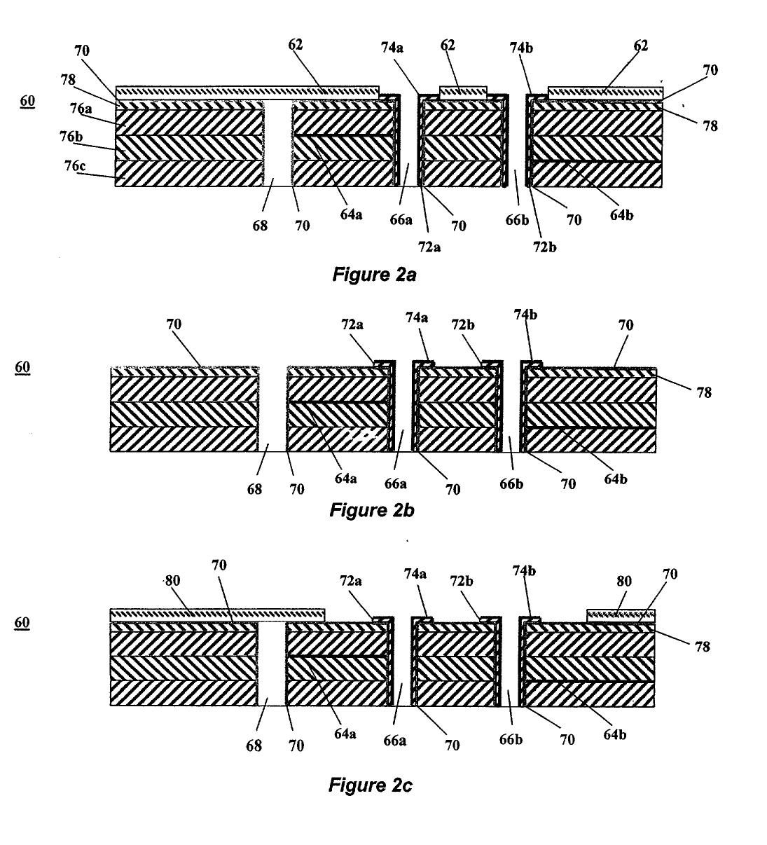

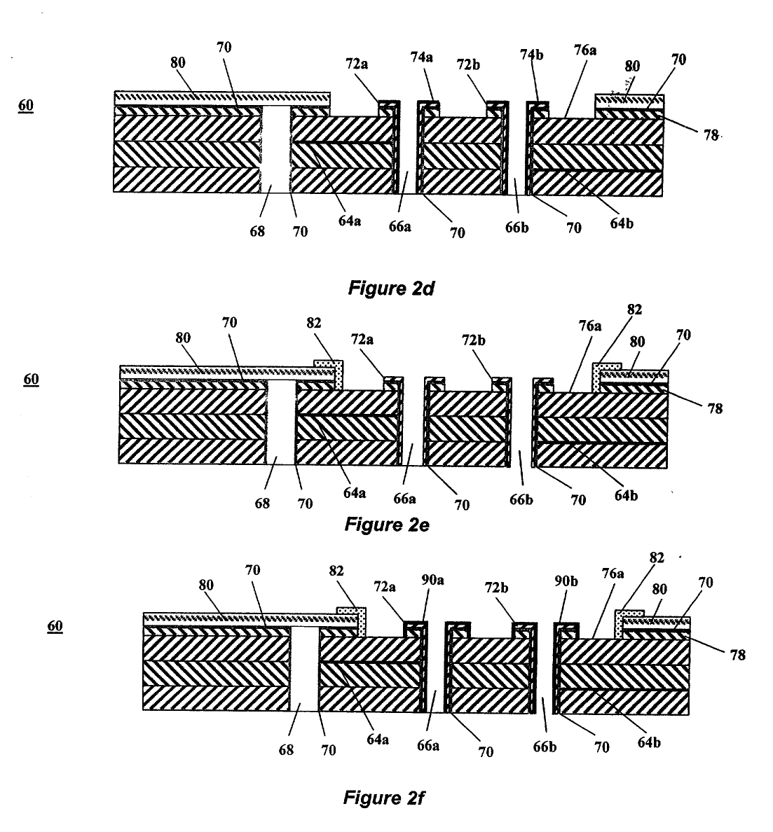

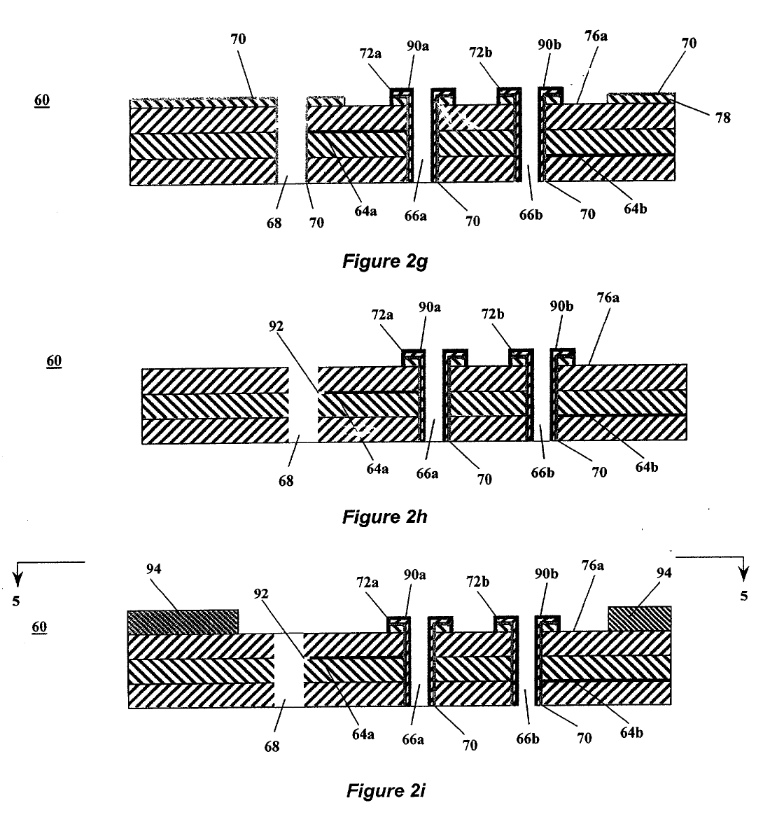

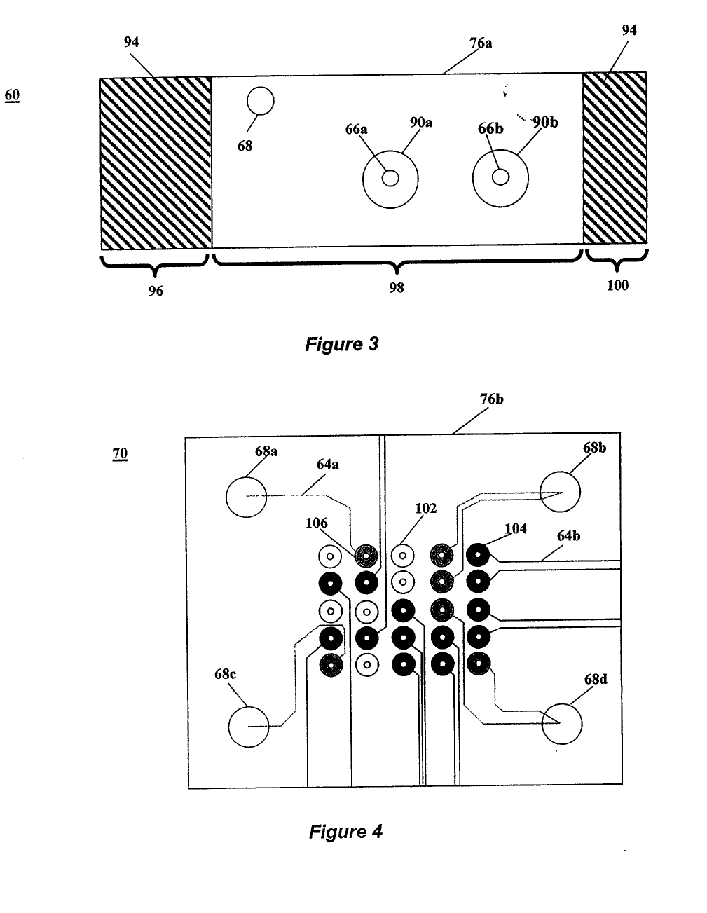

FIGS. 2a-2i and FIG. 3 provide a more detailed illustration a method that embodies steps (iii) through (vi) described above, i.e. after multi-layered PWB 60 is designed to include conductors internally connected between features which require gold finishes, and through holes to be used as temporary busses.

In FIGS. 2a-2i, and FIG. 3, PWB 60, is a multi-layered board, wherein only upper three copper clad laminas 76a, 76b, and 76c are shown. PWB 60 begins as a copper foil clad laminate where layer 78 is the copper foil cladding of the laminate. After the copper foil clad laminate is provided, through holes 68, 66a, and 66b are drilled in the laminate, and the entire drilled laminate is electrolessly plated to cover the all the surfaces of the laminate, including the walls of the through holes, with copper layer 70. After electrolessly plating copper layer 70 on all the surfaces, resist 62 is imaged onto the laminate, and additional build up of traces and through hole linings is accomplished by electrolytic plating of copper layers 72a and 72b, and tin layers 74a and 74b. Thus, as shown in FIG. 2a, through holes 66a, 66b, and 68 are shown drilled in PWB 60; electroless copper layer 70 is shown deposited on top of the copper clad lamina 76a and on the walls of the through holes 66a, 66b, and 68.

Referring to FIG. 2b, mask 62 is removed in a conventional manner, thus leaving the features (circular tabs) shown in FIG. 2b and FIG. 3. It will be appreciated that the features could be of any shape, but are shown as circular tabs for exemplary purposes. The steps illustrated by FIGS. 2a and 2b are preferably performed in the sequence described, but may be performed in any conventional manner.

A new mask is patterned to mask all areas of the PWB that do not require gold finishes. Therefore, referring to FIG. 2c and FIG. 3, non-gold-area-mask 80 is applied and developed as resists on the external surfaces of PWB 60. Thus, non-masked area 98, shown in FIG. 3, is not masked.

Copper foil layer 78 and electroless copper layer 70 are then etched from the surface of non-masked region 98. It will be appreciated that circular tabs 72a and 72b are protected from the etching of copper, because the tin or solder (tin-lead) 74a and 74b residing on these circular tabs are an etch-resist to copper etching as shown in FIG. 2d and FIG. 3.

After extraneous copper has been removed from non-masked region 98, the tin or solder (tin-lead) on the circular tabs (layers 74a and 74b in FIGS. 2c and 5d) is stripped.

Next, a new mask is patterned to mask the area around the area to be gold plated. Therefore, referring to FIG. 2e, a gold plate mask, 82 covers both the non-gold-area-mask 80 and the interface of the electroless copper layer 70 and the interface of the base foil copper layer 78. The reason for this mask is to prevent gold from plating on the metallic interface. If this mask is not applied, a thin gold sliver will be formed in subsequent stripping and etching operations. Since this mask must cover a three-dimensional area, the preferred method of resist coating is vacuum lamination.

Next, gold is electroplated on the circular tabs. This step is possible because all the copper features within the gold area have been internally connected to un-etched copper that is located outside of the gold areas and is electrically connected to an electroplating current source. For example, copper feature 72a is electrically connected to electroless copper plated through hole 68 that in turn is connected to un-etched copper layer 70, shown in FIG. 2f. It will be appreciated that gold is deposited on all exposed copper including the sidewalls of the copper features.

Subsequent processing of PWB 60 is accomplished in a typical fashion. Mask 80 and 82 are removed in a conventional manner, thus leaving the features (circular tabs) shown in FIG. 2g. The additional copper features (not shown) that are to remain copper still have tin or solder (tin-lead) as an etch resist on top of the copper.

As can be seen in FIG. 2h, electroless copper layer 70 and the base copper foil layer 78 is now etched in regions 96 and 100. Previously plated tin or solder (tin-lead) protects the surface features outside the gold area. The etching process severs the electrical bus connection 64a connecting through hole 66a with non-plated through hole 68. Although the non-plated through hole 68 was originally used as an electrical connection the final etching process has converted this electroless copper metalized through hole to a non-plated through hole. Therefore, the electrical bus connection 64a has been severed by removal of the electroless copper layer 70 and the base foil copper 78. It is also noted that the etching process removes the end of the bus connection 64a back towards the gold plated through hole 66a for a distance 92 of 0.001″ to 0.002″. This makes the non-plated through hole serviceable for metallic mounting hardware such as bolts (not shown).

The plated tin or solder (tin-lead), may be stripped away in a conventional manner, if the PWB requires SMOBC, (solder mask over bare copper) finish. If a SMOBC finish is not required, then the plated solder may be re-flowed. Finally, if required a solder mask 94 may be applied and a protective OSP coating for solderable surfaces as shown in FIG. 2i. Both may be done in a conventional manner.

It is interesting to note that application of the disclosed method results in a device having a unique structure, particularly in regard to having a plurality of internal traces intersecting a non-plated through hole. Such a structure is illustrated in FIG. 1c in which a multi-layered semiconductor device 100 formed through the use of the disclosed plating method comprises a plurality of features 111 (pads in the embodiment shown) electroplated with a noble metal 113. The nobly electroplated features 111 are each electrically coupled to conductors/traces 140 embedded within the mutli-layered semiconductor device 100. Conductors 140 are electrically isolated from each other. Each conductor 140 is electrically coupled to a plated feature 111, and intersects a common non-plated through hole 130.

It should be noted that the term “intersects” as used herein is also meant to encompass the arrangement shown in FIG. 2i, wherein the bus connection 64a is etched away from the non-plated through hole 68 by a small distance 92, and does not actually contact or cross the cylindrical wall of the through hole 68 due to a small removal of material during processing.

Although illustrated and described herein with reference to certain specific embodiments, the present invention is nevertheless no intended to be limited to the details shown. Rather, various modifications may be made in the details within the scope and range of equivalents of the claims and without departing from the spirit of the invention. It will be understood, for example, that the present invention is not limited to only gold features. Rather, the invention may be extended to other noble metals beyond gold, such as silver, and palladium, and may also be extended to non-noble metals. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

What is claimed is:

1. A multi-layered semiconductor device comprising at least two features, each feature being electroplated with a noble metal, and each electroplated feature being coupled to one of at least two conductors embedded within the mutli-layered semiconductor device, wherein the at least two conductors are electrically isolated from each other and intersect a common non-plated via or through hole.

2. The multi-layered semiconductor device of claim 1 wherein the multi-layered semiconductor device is a printed wiring board (PWB) and each of the electroplated features is a via or through hole.

3. The PWB of claim 2 further comprising a fastener received by the non-plated via or through hole, the fastener being either non-conductive or electrically disconnected from the at least two conductors.

4. A method of plating comprising:
providing a device having a plurality of features to be selectively plated wherein each of the plurality of features to be selectively plated is electrically coupled to a metalized via or through hole;
selectively plating the plurality of features to be plated;
converting the metalized via or through hole to a non-metalized via or through hole.

5. The method of claim 4 wherein converting the metalized via or through hole comprises etching the via or through hole to remove the metalization.

6. The method of claim 4 wherein converting the metalized via or through hole comprises drilling the via or through hole to remove the metalization.

7. The method of claim 4 further comprising inserting a fastener into the non-metalized via or through hole.

8. A method of selectively plating features of a printed wiring board (PWB) formed in accordance with a PWB design, the PWB having at least one portion adapted to be coupled to a current source during electroplating, the method comprising:
using the PWB design to identify features of the PWB which are to be selectively plated, but which will be electrically isolated from the at least one portion of the PWB adapted to be coupled to a current source during electroplating;
using the PWB design to identify non-plated through holes which will be used as temporary busses during plating;
modifying the PWB design by adding conductors that will electrically connect the identified features to be plated with the temporary busses;
providing a PWB that at least partially corresponds to the PWB design by including the identified features, identified through holes, and added conductors;
forming the temporary busses out of the identified through holes;
selectively plating the identified features; and
electrically isolating at least some of the added conductors from each other after selective plating is complete.

9. The method of claim 8 wherein the step of using the PWB design to identify non-plated through holes which will be used as temporary busses during plating follows a step of modifying the PWB design by adding at least one non-plated through hole that will be used as a temporary bus during plating, the at least one added through hole being one of the identified non-plated through holes.

10. The method of claim 8 further comprising modifying the PWB design by adding conductors which will electrically connect the temporary busses to a current source during plating.

11. The method of claim 8 wherein the step of forming the temporary busses comprises temporarily plating the walls of the identified through holes.

12. The method of claim 8 wherein the step of forming the temporary busses comprises temporarily filling the identified through holes with an electrically conductive material.

13. The method of claim 8 wherein the step of electrically isolating at least some of the added conductors from each other after selective plating is complete comprises removing conductive material from at least one of the temporary busses.

14. The method of claim 13 wherein removing conductive material from at least one of the temporary busses is accomplished by drilling or etching.
